(19) United States
(12) Patent Application Publication
(10) Pub. No.: US 2026/0129743 A1
(43) Pub. Date: May 7, 2026

(54) PRINTED CIRCUIT BOARDS FOR SIMPLIFIED HEATSINK ASSEMBLIES

(71) Applicant: AcLeap Power Inc., Taipei City (TW)

(72) Inventors: John Andrew Trelford, Richardson, TX (US); Donald P. Rearick, Nevada, TX (US); Pedro Angel Fernandez, Plano, TX (US); Stephen Lawrence Orona, JR., Wylie, TX (US)

(21) Appl. No.: 18/937,660

(22) Filed: Nov. 5, 2024

(51) Int. Cl. H05K 1/02

(52) U.S. Cl. CPC H05K 1/021; H05K 1/0298; H05K 2201/066

(57) ABSTRACT

A PCB includes a plurality of insulating layers, first, second, third, and fourth copper areas, first and second plurality of vias, and at least one inner copper area. The insulating layers include a first side and a second side opposite the first side and a plurality of fingers disposed along a perimeter. The first and second copper areas are disposed on the first and second sides respectively. The third and fourth copper areas are disposed on the first and second sides respectively at a finger of the plurality of fingers. The first plurality of vias are electrically coupled to the first copper area and partially extend from the first copper area towards the second copper area. The second plurality of vias electrically couple the third and fourth copper areas together, and the at least one inner copper area electrically couples the first and second plurality of vias together.

### BACKGROUND

The field of the disclosure relates to printed circuit boards (PCBs), and in particular, to PCBs for power modules that include power semiconductor devices and heatsinks.

Power converter modules include power semiconductor devices, and depending on the power output of the power converter module, may include heatsinks that dissipate heat generated by the power semiconductor devices. The power semiconductor devices and the heatsinks may be manually installed on a PCB, forming a power converter module that may be subsequently connected to a main PCB.

FIG. 1 depicts a front perspective view of a heatsink assembly 100 as known, and FIGS. 2 and 3 depict a front view and side view, respectively, of the heatsink assembly 100.

In FIGS. 1-3, heatsink assembly 100 includes a heatsink 102, four through-hole leaded power semiconductors 104, 106, 108, 110, four screws 112, 114, 116, 118, and an electrical insulator 120. Prior to installing heatsink assembly 100 onto a PCB, such as a PCB used as a power converter module, heatsink assembly 100 may be hand-assembled. During the hand assembly, plastic lead insulators 122, 124 are fit over the pins of power semiconductors 104, 106, 108, 110, electrical insulator 120 is placed between power semiconductors 104, 106, 108, 110 and heatsink 102, and screws 112, 114, 116, 118 are used to secure power semiconductors 104, 106, 108, 110 to heatsink 102. Electrical insulator 120 is used to electrically isolate metal areas on the back of power semiconductors 104, 106, 108, 110 (not shown) from heatsink 102. The metal areas on the back of power semiconductors 104, 106, 108, 110 are typically electrically and thermally coupled to a high power sections of power semiconductors 104, 106, 108, 110, such as a drain of a metal-oxide field-effect transistor (MOSFET), and are used to improve the thermal conductivity between the die(s) of power semiconductors 104, 106, 108, 110 and heatsink 102. Heatsink assembly 100 may also include one or more leaded thermistors used to measure the temperatures of heatsink assembly 100, which may be hand-soldered and manually mounted.

The manufacturing and assembly of this type of heat sink assembly is labor-intensive and prone to errors. For example, the misalignment of the pins for power semiconductors 104, 106, 108, 110 may result in the pins not aligning with holes in the PCB for the power converter module, resulting in a manual re-work for heatsink assembly 100. In another example, metal shavings, metal particles, and/or defects in electrical insulator 120 may result in shorts between power semiconductors 104, 106, 108, 110 and heatsink 102, which is undesirable. Shorts between power semiconductors 104, 106, 108, 110 and heatsink 102 may result in failures in power semiconductors 104, 106, 108, 110, unexpected voltages at heatsink 102, and/or unintended magnetic fields generated by heatsink 102.

Thus, it is desirable to improve the assembly process for semiconductor devices and heatsinks used for power converter modules, such as DC-DC converter modules.

### BRIEF DESCRIPTION

In one embodiment, a PCB is provided. The PCB includes a plurality of insulating layers, first and second copper areas, third and fourth copper areas, a first plurality of vias, a second plurality of vias, and at least one inner copper area. The plurality of insulating layers include a first side and a second side opposite the first side, where the plurality of insulating layers include a plurality of fingers disposed along a perimeter of the plurality of insulating layers. The first and second copper areas are disposed on the first and second sides respectively. The third and fourth copper areas are disposed on the first and second sides respectively, where the third and fourth copper areas are disposed at a finger of the plurality of fingers. The first plurality of vias are electrically coupled to the first copper area, where the first plurality of vias partially extend from the first copper area towards the second copper area. The second plurality of vias electrically couple the third and fourth copper areas together, and the at least one inner copper area electrically couples the first and second plurality of vias together.

In another embodiment, a power module is provided. The power module includes a PCB, a power semiconductor device, and a heatsink. The PCB includes a plurality of insulating layers, first and second copper areas, third and fourth copper areas, a first plurality of vias, a second plurality of vias, and at least one inner copper area. The plurality of insulating layers include a first side and a second side opposite the first side, where the plurality of insulating layers include a plurality of fingers disposed along a perimeter of the plurality of insulating layers. The first and second copper areas are disposed on the first and second sides respectively. The third and fourth copper areas are disposed on the first and second sides respectively, where the third and fourth copper areas are disposed at a finger of the plurality of fingers. The first plurality of vias are electrically coupled to the first copper area, where the first plurality of vias partially extend from the first copper area towards the second copper area. The second plurality of vias electrically couple the third and fourth copper areas together, and the at least one inner copper area electrically couples the first and second plurality of vias together. The power semiconductor device includes a power terminal soldered to the first copper area and the heatsink is soldered to the second copper area.

In another embodiment, a power module is provided. The power module includes a PCB, a power semiconductor device, and a heatsink. The PCB includes a first copper area disposed on a first side of the PCB, a second copper area disposed on a second side of the PCB opposite the first side, and third and/or fourth copper areas disposed on the first and/or second sides, respectively. The first and second copper areas are electrically isolated from each other, and the third and/or fourth copper areas are electrically coupled to the first copper area. The power semiconductor device includes a power terminal soldered to the first copper area, and the heatsink is soldered to the second copper area.

### BRIEF DESCRIPTION OF DRAWINGS

These and other features, aspects, and advantages of the present disclosure will become better understood when the following detailed description is read with reference to the accompanying drawings in which like characters represent like parts throughout the drawings.

FIG. 1 depicts a front perspective view of a known heatsink assembly.

FIG. 2 depicts a front view of the heatsink assembly of FIG. 1.

FIG. 3 depicts a side view of the heatsink assembly of FIG. 1.

FIG. 4 depicts a front view of a PCB for a power delivery module in exemplary embodiment.

FIG. 5 depicts a back view of the PCB of FIG. 4.

FIG. 6 depicts a front view of a power module in an exemplary embodiment.

FIG. 7 depicts a side view of the power module of FIG. 6.

FIG. 8 depicts a front perspective view of another power module in an exemplary embodiment.

FIG. 9 depicts a rear perspective view of another power module in an exemplary embodiment.

FIG. 10 depicts a cross-section of a portion of the PCB of FIG. 4 for the power module of FIG. 6 in an exemplary embodiment.

FIG. 11 depicts a cross-section of a portion of the PCB of FIG. 4 for the power module of FIG. 6 in another exemplary embodiment.

FIG. 12 depicts a cross-section of a portion of the PCB of FIG. 4 for the power module of FIG. 6 in another exemplary embodiment.

Unless otherwise indicated, the drawings provided herein are meant to illustrate features of embodiments of this disclosure. These features are believed to be applicable in a wide variety of systems comprising one or more embodiments of this disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately”, and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

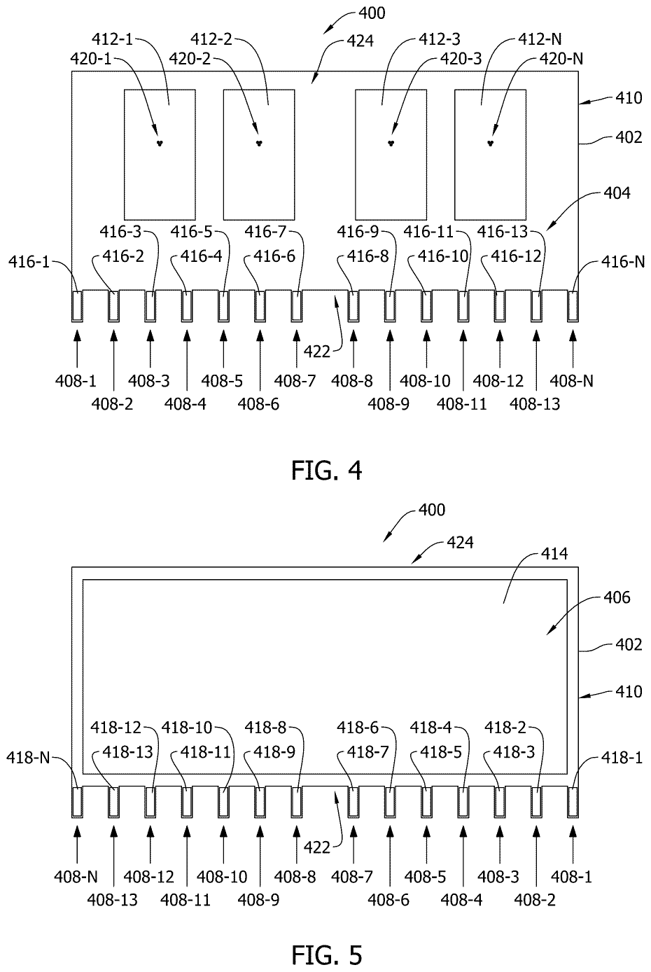

FIG. 4 depicts a front view of a PCB 400 for a power module in an exemplary embodiment, and FIG. 5 depicts a back view of PCB 400. In this embodiment, PCB 400 includes a plurality of insulating layers 402 laminated together (the individual insulating layers are not shown in FIGS. 4 and 5). Insulating layers 402 have a front side 404 (also referred to as a first side) and an opposing back side 406 (also referred to as a second side).

In this embodiment, insulating layers 402 include a plurality of fingers 408-1, 408-2, 408-3, 408-4, 408-5, 408-6, 408-7, 408-8, 408-9, 408-10, 408-11, 408-12, 408-13, 408-N, collectively referred to as fingers 408, where N is an arbitrary number. In this embodiment, fingers 408 are located along a perimeter 410 of insulating layers 402, and in particular, are formed by notching out portions of insulating layers 402 along one edge of insulating layers 402.

In this embodiment, PCB 400 further includes, at front side 404 of insulating layers 402, heat spreaders 412-1, 412-2, 412-3, 412-N, collectively referred to as heat spreaders 412 (also referred to as first copper areas). Heat spreaders 412 are formed from copper, and may be patterned by etching away a copper layer bonded to front side 404 of insulating layers 402 when manufacturing PCB 400. When PCB 400 is utilized as part of a power module, one or more power semiconductor devices (not shown) may be soldered or otherwise bonded to heat spreaders 412, and heat spreaders 412 function to spread the heat generated by the power semiconductor devices over a wider area on PCB 400. In some embodiments, heat spreaders 412 are exposed for soldering (e.g., exposed by a solder mask relief around heat spreaders 412), and heatsinks may be soldered or otherwise bonded to heat spreaders 412 on front side 404 of insulating layers 402.

Referring to FIG. 5, PCB 400 further includes, at back side 406 of insulating layers 402, a copper area 414 (also referred to as a second copper area) that extends over a major portion of back side 406 of insulating layers 402. Copper area 414 may be patterned by etching away a copper layer bonded to back side 406 of insulating layers 402 when manufacturing PCB 400. Generally, some or all of copper area 414 is exposed for soldering (e.g., exposed by a solder mask relief around copper area 414) such that one or more heatsinks (not shown) may be soldered or otherwise bonded to copper area. 414.

When PCB 400 is utilized as part of a power module, the heat transferred to heat spreaders 412 (see FIG. 4) at front side 404 of insulating layers 402 is thermally transferred to copper area 414 at back side 406 of insulating layers 402, which is dissipated by a heatsink (not shown) coupled to copper area 414 on back side 406 of insulating layers 402.

In this embodiment, PCB 400 further includes front side copper pads 416-1, 416-2, 416-3, 416-4, 416-5, 416-6, 416-7, 416-8, 416-9, 416-10, 416-11, 416-12, 416-13, 416-N, located at front side 404 of insulating layers 402 and collectively referred to as front side copper pads 416 (also referred to as third copper areas), where N is an arbitrary number. Each of fingers 408-1, 408-2, 408-3, 408-4, 408-5, 408-6, 408-7, 408-8, 408-9, 408-10, 408-11, 408-12, 408-13, 408-N includes one of front side copper pads 416-1, 416-2, 416-3, 416-4, 416-5, 416-6, 416-7, 416-8, 416-9, 416-10, 416-11, 416-12, 416-13, 416-N, respectively.

PCB 400 further includes back side copper pads 418-1, 418-2, 418-3, 418-4, 418-5, 418-6, 418-7, 418-8, 418-9, 418-10, 418-11, 416-12, 418-13, 418-N, located at back side 406 of insulating layers 402 and collectively referred to as back side copper pads 418 (also referred to as fourth copper areas), where N is an arbitrary number. Each of fingers 408-1, 408-2, 408-3, 408-4, 408-5, 408-6, 408-7, 408-8, 408-9, 408-10, 408-11, 408-12, 408-13, 408-N includes one of back side copper pads 418-1, 418-2, 418-3, 418-4, 418-5, 418-6, 418-7, 418-8, 418-9, 418-10, 418-11, 416-12, 418-13, 418-N, respectively. Front side copper pads 416 and back side copper pads 418 may be patterned by etching away copper layers bonded to front side 404 of insulating layers 402 and back side 406 of insulating layers 402, respectively, when manufacturing PCB 400

When PCB 400 is utilized as part of a power module, front and back side copper pads 416, 418 carry electrical power, ground, signals, and currents to and from the components mounted to PCB 400. Fingers 408 may be inserted into holes or other features in a main PCB (not shown) and wave soldered into place.

In this embodiment, each of heat spreaders 412-1, 412-2, 412-3, 412-N include a plurality of vias 420-1, 420-2, 420-3, 420-N, respectively, collectively referred to as vias 420, where N is an arbitrary number. Vias 420-1, 420-2, 420-3, 420-N are structures that allow signals, power, and ground to travel between insulating layers 402. Although three vias 420 are shown for each of heat spreaders 412, heat spreaders 412 may include any number of vias 420 (e.g., hundreds). Generally, vias 420 are electrically coupled to heat spreaders 412 and electrically isolated from copper area 414 on back side 406 of insulating layers 402. This prevents electrical shorts between the different power semiconductor devices that may be soldered to heat spreaders 412. Vias 420 may include, for example, combinations of controlled depth blind vias and buried vias that only extend partially through insulating layers 402 from front side 404 towards back side 406.

Although heat spreaders 412, copper area 414, and front and back side copper pads 416, 418 have been depicted having a specific shape, orientation, or area on PCB 400, heat spreaders 412, copper area 414, and front and back side copper pads 416, 418 may have different shapes, orientations, or areas in other embodiments.

For example, the number of heat spreaders 412 may vary depending on the number of power semiconductor devices installed at PCB 400 when PCB 400 forms a power module. In another example, copper area 414 on back side 406 of insulating layers 402 may be segmented into separate areas, each associated with a different heatsink that is smaller than defined by the area of copper area 414 illustrated in FIG. 5. When copper area 414 is segmented into different copper areas, each of the different copper areas may substantially align with one of heat spreaders 412 in order to reduce a thermal path length between heat spreaders 412 and their corresponding heatsink on back side 406 of insulating layers 402.

In FIG. 4, fingers 408 partially extend along perimeter 410 of insulating layers 402. In particular, fingers 408 extend along a first edge 422 of insulating layers 402 and heat spreaders 412 are located closer to a second edge 424 of insulating layers 402 that opposes first edge 422. As depicted in FIGS. 4 and 5, heat spreaders 412 and copper area 414 extend substantially between first and second edges 422, 424. In particular, heat spreaders 412 may extend at least fifty percent of the distance between first and second edges 422, 424, and copper area 414 may extend at least ninety percent between first and second edges 422, 424. In other words, heat spreaders 412 and copper area 414 are more than simply the typical copper traces or copper pads on PCB 400 for integrated circuits, but rather, are substantial copper areas that may have a weight up to ten ounces of copper per square foot in order to effectively operate as heat spreading and heat dissipation features on PCB 400.

Further, although not depicted in FIGS. 4 and 5, front and/or back sides 404, 406 of insulating layers 402 may include other copper features not shown, including copper traces, copper pads, features for connectors (e.g., surface mount pads, plated holes, etc.) that may, in some embodiments, be used in addition to or instead of fingers 408 to route power, ground, and signals to and/or from PCB 400, etc. This will be discussed later.

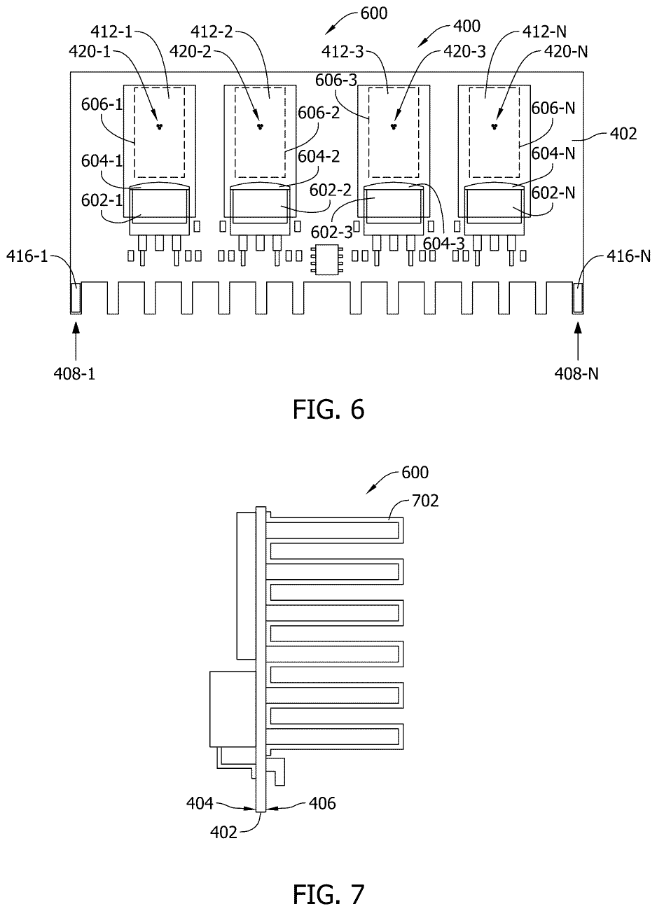

FIG. 6 depicts a front view of a power module 600 in an exemplary embodiment. In this embodiment, power module 600 utilizes PCB 400 of FIGS. 4 and 5. In this embodiment, power module 600 includes a plurality of power semiconductor devices 602-1, 602-2, 602-3, 602-N, collectively referred to as power semiconductor devices 602, where N is an arbitrary number. In this embodiment, each of power semiconductor devices 602-1, 602-2, 602-3, 602-N includes a power terminal 604-1, 604-2, 604-3, 604-N, respectively, collectively referred to as power terminals 604, where N is an arbitrary number. Power semiconductor devices 602 may include MOSFETS, silicon controlled rectifiers (SCR), insulated-gate bipolar transistors (IGBTs), diodes, thyristors, or other types of power electronics devices.

Each of power terminals 604-1, 604-2, 604-3, 604-N are soldered or otherwise bonded to a respective one of heat spreaders 412-1, 412-2, 412-3, 412-N. Power terminals 604 are therefore electrically and thermally coupled with heat spreaders 412. Power terminals 604 may include, for example, a metal tab on a surface mount package, such as a D2PAK, DPAK, metal areas on the bottom of an SO-8, metal areas on the bottom of a power quad flat no-lead (PQFN) package, metal areas on the bottom of chip scale packages (CSP's), metal areas on the bottom of other types of packaging, and/or metal areas for other types of surface mount device packaging for power semiconductor devices.

In addition to power semiconductor devices 602, PCB 400 may include other devices, such as snubber circuits, surface mount thermistors, drivers for power semiconductor devices 602, etc.

FIG. 7 depicts a side view of power module 600. In FIG. 7, a heatsink 702 is visible, and heatsink 702 is soldered or otherwise bonded to copper area 414 (see FIG. 5) at back side 406 of insulating layers 402. Heatsink 702 may comprise, for example, a folded fin heat sink.

During the operation of power module 600, the heat generated by power semiconductor devices 602 is spread out by heat spreaders 412, and the heat travels perpendicular through PCB 400 utilizing vias 420 towards copper area 414 on back side 406 of insulating layers 402. Heatsink 702 is electrically and thermally coupled with copper area 414, and heatsink 702 operates to dissipate the heat generated by power semiconductor devices 602. As discussed previously, vias 420 do not extend through insulating layers 402 in PCB 400, and therefore, power semiconductor devices 602 are not electrically coupled to heatsink 702. Although not shown in FIGS. 6 and 7, one or more heat spreaders 412 may also include additional heatsinks 606-1, 606-2, 606-3, 606-N soldered or otherwise bonded to their respective heat spreaders 412-1, 412-2, 412-3, 412-N in order to improve the heat dissipation capacity of power module 600. In some embodiments, heat spreaders 412 may be placed under power semiconductor devices 602 depending on the amount of heat generated by power semiconductor devices 602.

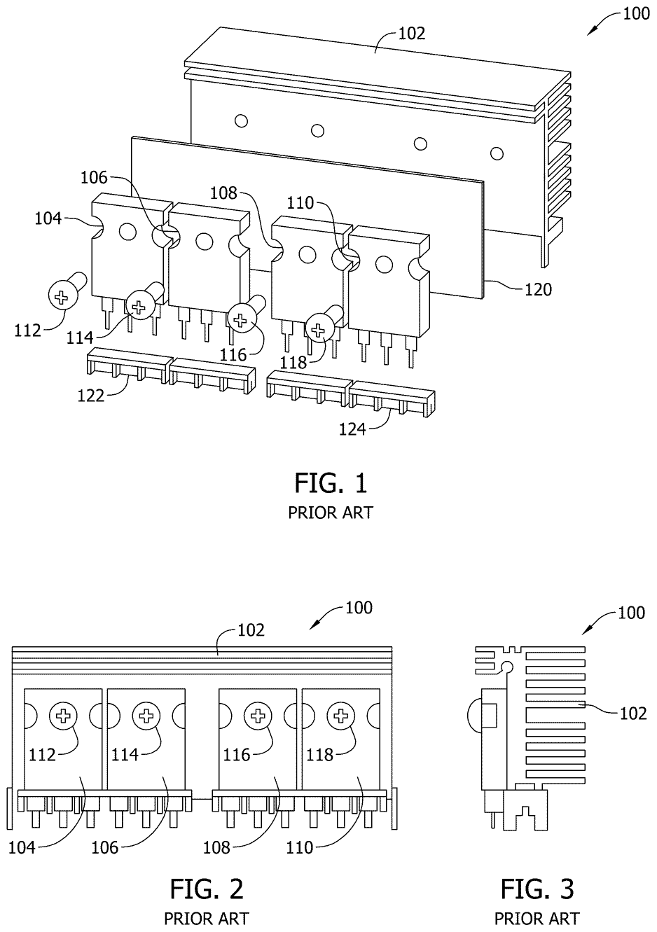

Power module 600 provides a number of advantages over heatsink assembly 100 of FIG. 1, including (a) eliminating screws, plastic lead insulators for power semiconductor devices 602, and a heatsink insulator for heatsink 702; (b) eliminating tapped holes and mechanical hardware in heatsink 702; (c) eliminating the manual assembly process for assembling heatsink assembly 100; (d) eliminating through-hole power semiconductor device pin fixtures used for alignment during assembly of heatsink assembly 100; (e) eliminating leaded thermistors for power module 600, which may use surface mount thermistors at PCB 400; (f) eliminating a lead trim process for the through-hole power semiconductor devices; (g) reducing space used on a main board for components that can be moved to PCB 400, such as snubbers, drivers, thermistors, etc., which can be placed closer to power semiconductor devices 602 for improved power density; (h) providing the ability to cool additional components on PCB 400 by heatsink 702; (i) modifying the pitch of fingers 408 as needed using different configurations of PCB 400 depending on the application; (j) the use of heat spreaders 412 improve the thermal performance of the solution; (k) the use of a folded fin heatsink, such as heatsink 702, improves the surface area of heatsink 702 by forty one percent or more as compared to heatsink 102 (see FIG. 1); (l) the use of a folded fin heatsink, such as heatsink 702, reduces a weight of heatsink 702 by sixty five percent or more as compared to heatsink 102; (m) typical surface mount packages are smaller and denser than their through-hole counterparts, and more surface mount packages can fit on the same PCB area; (n) power semiconductor devices 602 may be removed and replaced more easily during rework as compared to power devices 104, 105, 108 of heatsink assembly 100; (o) folded fin heatsinks, such as heatsink 702, may use pre-plated aluminum or copper, which may be cheaper than performing a post-plating operation on a heatsink; and (p) eliminating quality issues when attaching power devices 104, 106, 108. 110 to heatsink 102 using screws 112, 114, 116, 118.

Further, although not depicted in FIGS. 6 and 7, front and/or back sides 404, 406 of insulating layers 402 may include connectors (e.g., surface mount connectors, through hole connectors, etc.) that may, in some embodiments, be used in addition to or instead of fingers 408 to route power, ground, and signals to and/or from PCB 400, etc. This will be discussed later.

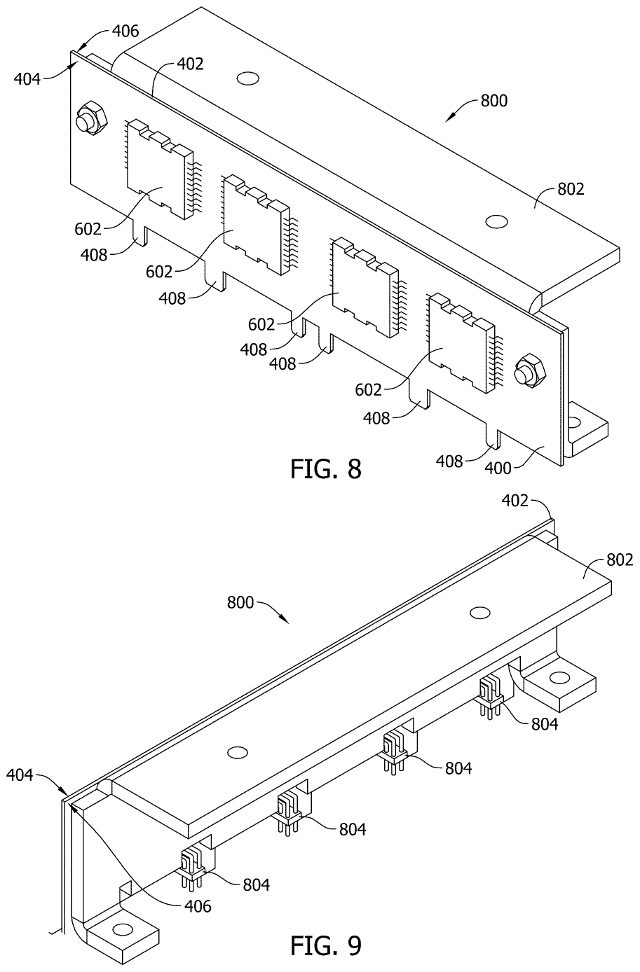

FIG. 8 depicts a front perspective view of another power module 800 in an exemplary embodiment, and FIG. 9 depicts a rear perspective view of power module 800. In this embodiment, power module 800 includes a heat dissipater 802 coupled to PCB 400. Heat dissipater 802 may operate similarly as previously described with respect to heatsink 702 to dissipate heat from power semiconductor devices 602 (with heat spreaders 412 located under metal pads of power semiconductor devices 602, not shown, that are used to thermally couple power semiconductor devices 602 to heat dissipater 802). In this embodiment, PCB 400 includes fingers 408. In addition to or instead of, power module 800 may include connectors 804, which operate similar to fingers 408, front side copper pads 416, and back side copper pads 418 to route power, ground, and signals to and/or from PCB 400.

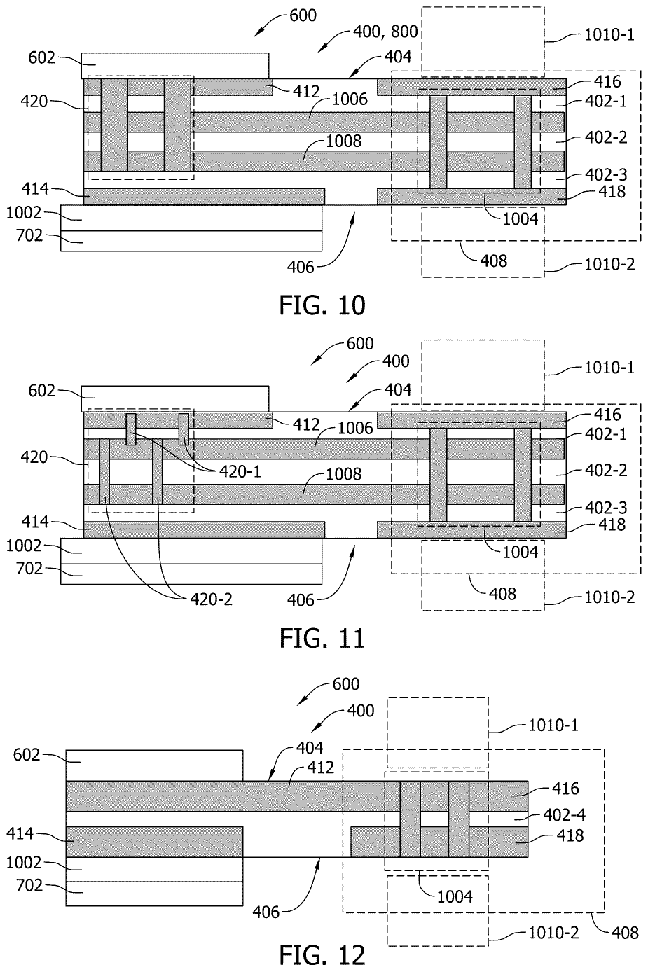

FIG. 10 depicts a cross-section of a portion of PCB 400 of power module 600 in an exemplary embodiment. In this embodiment, PCB 400 is a four layer board formed from three insulating layers 402-1, 402-2, 402-3 laminated together. In this embodiment, vias 420 are controlled depth blind vias, and vias 420 extend through heat spreader 412 and insulating layers 402-1, 402-2. Vias 420 do not extent through insulating layer 402-3, and therefore, power semiconductor device 602 and heat spreader 412 are electrically isolated from copper area 414 and heatsink 702. In this embodiment, heatsink 702 is electrically and thermally coupled to copper area 414 using solder 1002.

In this embodiment, top side copper pad 416 and bottom side copper pad 418 are electrically coupled together using vias 1004, which are through-hole vias in this embodiment. Vias 1004 extend through insulating layers 402-1, 402-2, 402-3 at finger 408. Further in this embodiment, inner copper areas 1006, 1008 electrically couple vias 420, 1004 together, such that heat spreader 412 is electrically coupled with top and bottom side copper pads 416, 418. Therefore, current may be conducted from the power terminal of power semiconductor device 602 through vias 420, inner copper areas 1006, 1008, and vias 1004 to top and bottom side copper pads 416, 418 of PCB 400 at finger 408. In some embodiments, some or all of vias 1004 may be replaced with plated through holes.

In some embodiments, connector 1010-1 and/or connector 1010-2 may be soldered to top side copper pad 416 and/or bottom side copper pad 418, respectively. In these embodiments, PCB 400 may not include fingers 408, and top side copper pad 416 and bottom side copper pad 418 may be located at positions on PCB 400 that are not on fingers 408. Connectors 1010-1, 1010-2 may include surface mount connectors, through hole connectors, etc.

FIG. 11 depicts a cross-section of a portion of PCB 400 of power module 600 in another exemplary embodiment. In this embodiment, vias 420 are formed as combination of laser-drilled controlled-depth vias 420-1, which extend through insulating layer 402-1 and electrically couple heat spreader 412 to inner copper areas 1006, and buried vias 420-2, which extend through insulating layer 402-2 and electrically couple inner copper areas 1006, 1008 together.

FIG. 12 depicts a cross-section of a portion of PCB 400 of power module 600 in another exemplary embodiment. In this embodiment, PCB 400 includes only one insulating layer 402-4, and vias 420 in heat spreader 412 are not used. Heat spreader 412 and copper area 414 for heatsink 702 are electrically isolated from each other by insulating layer 402-4, and heat spreader 412 and front side copper pad 416 are the same copper layer on first side 404 of PCB 400.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the embodiments, including the best mode, and also to enable any person skilled in the art to practice the embodiments, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A printed circuit board (PCB) comprising:
a plurality of insulating layers comprising a first side and a second side opposite the first side, wherein the plurality of insulating layers includes a plurality of fingers disposed along a perimeter of the plurality of insulating layers;
first and second copper areas disposed on the first and second sides respectively;
third and fourth copper areas disposed on the first and second sides respectively, wherein the third and fourth copper areas are disposed at a finger of the plurality of fingers;
a first plurality of vias electrically coupled to the first copper area, wherein the first plurality of vias partially extend from the first copper area towards the second copper area;
a second plurality of vias electrically coupling the third and fourth copper areas together; and
at least one inner copper area electrically coupling the first and second plurality of vias together.

2. The PCB of claim 1, wherein:
the first plurality of vias comprise controlled depth blind vias and/or buried vias.

3. The PCB of claim 1, wherein:
the second plurality of vias comprise through-hole vias.

4. The PCB of claim 1, wherein:
the first plurality of vias partially extend from the first copper area towards the second copper area such that the first copper area is electrically isolated from the second copper area by an insulating layer of the plurality of insulating layers.

5. The PCB of claim 1, wherein:
the at least one inner copper area comprises two inner copper areas on different layers of the plurality of insulating layers.

6. A power module, comprising:
a printed circuit board (PCB) comprising:
a plurality of insulating layers comprising a first side and a second side opposite the first side, wherein the plurality of insulating layers includes a plurality of fingers disposed along a perimeter of the plurality of insulating layers;
first and second copper areas disposed on the first and second sides respectively;
third and fourth copper areas disposed on the first and second sides respectively, wherein the third and fourth copper areas are disposed at a finger of the plurality of fingers;
a first plurality of vias electrically coupled to the first copper area, wherein the first plurality of vias partially extend from the first copper area towards the second copper area;
a second plurality of vias electrically coupling the third and fourth copper areas together; and
at least one inner copper area electrically coupling the first and second plurality of vias together;
a power semiconductor device having a power terminal soldered to the first copper area; and
a heatsink soldered to the second copper area.

7. The power module of claim 6, wherein:
the first plurality of vias comprise controlled depth blind vias and/or buried vias.

8. The power module of claim 6, wherein:
the second plurality of vias comprise through-hole vias.

9. The power module of claim 6, wherein:
the first plurality of vias partially extend from the first copper area towards the second copper area such that the first copper area is electrically isolated from the second copper area by an insulating layer of the plurality of insulating layers.

10. The power module of claim 6, further comprising:
another heatsink soldered to the first copper area.

11. The power module of claim 6, wherein:
the power semiconductor device includes at least two pins, each electrically connected to copper areas disposed at different fingers of the plurality of fingers.

12. The power module of claim 6, wherein:
the at least one inner copper area comprises two inner copper areas on different layers of the plurality of insulating layers.

13. The power module of claim 6, wherein:
the heatsink comprises a folded fin heatsink.

14. A power module, comprising:
a printed circuit board (PCB) having a first copper area disposed on a first side of the PCB, a second copper area disposed on a second side of the PCB opposite the first side, and third and/or fourth copper areas disposed on the first and/or second sides, respectively, wherein the first and second copper areas are electrically isolated from each other, and wherein the third and/or fourth copper areas are electrically coupled to the first copper area;
a power semiconductor device having a power terminal soldered to the first copper area; and
a heatsink soldered to the second copper area.

15. The power module of claim 14, further comprising:
a connector soldered to the third and/or fourth copper areas.

16. The power module of claim 14, wherein:
the PCB includes a plurality of fingers disposed along a perimeter of the PCB, and
the third and/or fourth copper areas are disposed at a finger of the plurality of fingers.

17. The power module of claim 16, wherein:
the power semiconductor device includes at least two pins, each electrically connected to copper areas disposed at different fingers of the plurality of fingers.

18. The power module of claim 14, wherein the PCB further comprises:
a first plurality of vias electrically coupled to the first copper area that partially extend from the first copper area towards the second copper area;
at least one inner copper area electrically coupled to the first plurality of vias; and
a second plurality of vias and/or plated through holes electrically coupling the third and/or fourth copper areas to the at least one inner copper area.

19. The power module of claim 14, wherein:
the first copper area and the third copper area are a same copper layer on the first side of the PCB.

20. The power module of claim 14, wherein:
the heatsink comprises a folded fin heatsink.
